(19) United States
(12) Patent Application Publication
(10) Pub. No.: US 2026/0033321 A1
(43) Pub. Date: Jan. 29, 2026

(54) INTERCONNECT STRUCTURE AND MANUFACTURING METHOD THEREOF

(71) Applicant: Taiwan Semiconductor Manufacturing Company, Ltd., Hsin-Chu (TW)

(72) Inventors: Jing Ting SU, Hsinchu (TW); Shao-Kuan LEE, Kaohsiung City (TW); Kuang-Wei YANG, Hsinchu (TW); Hsin-Yen HUANG, New Taipei City (TW); Hsiao-Kang CHANG, Hsinchu City (TW)

(21) Appl. No.: 18/960,303

(22) Filed: Nov. 26, 2024

Related U.S. Application Data
(60) Provisional application No. 63/676,408, filed on Jul. 28, 2024.

(51) Int. Cl. H01L 23/528; H01L 21/768; H01L 23/522

(52) U.S. Cl. CPC H01L 23/5283; H01L 21/7684; H01L 21/76849; H01L 23/5226

(57) ABSTRACT

A method of forming a semiconductor structure includes forming a conductive feature in a first dielectric layer, depositing a second dielectric layer over the conductive feature, forming a first opening in the second dielectric layer to expose a top surface of the conductive feature, selectively depositing an inhibitor film on the top surface of the conductive feature, depositing a dielectric barrier layer on sidewalls of the first opening, removing the inhibitor film to expose the top surface of the conductive feature, depositing a conductive material over the dielectric barrier layer and filling the first opening, and performing a planarization process to expose the dielectric barrier layer.

### PRIORITY DATA

This application claims priority to U.S. Provisional Patent Application No. 63/676,408 filed on Jul. 28, 2024, the entire disclosure of which is incorporated herein by reference.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, as multilayer interconnect (MLI) features become more compact with ever-shrinking IC feature size, interconnects of the MLI features are exhibiting increased contact resistance, which presents performance, yield, and cost challenges. It has been observed that higher contact resistances exhibited by interconnects in advanced IC technology nodes can significantly delay (and, in some situations, prevent) signals from being routed efficiently to and from IC devices, such as transistors, negating any improvements in performance of such IC devices in the advanced technology nodes. Accordingly, although existing interconnects have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a cross-sectional view of layers involved in an interconnect structure of a semiconductor device, in accordance with some embodiments of the present disclosure.

FIGS. 2, 3, 4, 5, 6, 7, 8, 9, 10, 11, 12, 13, 14, 15, 16, 17, 18, 19, 20, 21, 22, 23, and 24 illustrate cross-sectional views of an interconnect structure at intermediate stages in the formation of one or more contact vias and metal lines, in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

IC manufacturing process flow is typically divided into three categories: front-end-of-line (FEOL), middle-end-of-line (MEOL), and back-end-of-line (BEOL). FEOL generally encompasses processes related to fabricating IC devices, such as transistors. For example, FEOL processes can include forming isolation features, gate structures, and source and drain features (generally referred to as source/drain features). MEOL generally encompasses processes related to fabricating contacts to conductive features (or conductive regions) of the IC devices, such as contacts to the gate structures and/or the source/drain features. BEOL generally encompasses processes related to fabricating a multilayer interconnect (MLI) feature that interconnects IC features fabricated by FEOL and MEOL (referred to herein as FEOL and MEOL features or structures, respectively), thereby enabling operation of the IC devices.

As IC technologies advance toward smaller technology nodes, MEOL and BEOL processes are experiencing significant challenges. For example, advanced IC nodes demand more compact multilayer interconnect (MLI) features, necessitating significant reductions in the critical dimensions of interconnect components such as the widths and heights of vias and conductive lines. However, these reduced critical dimensions have led to significant increases in interconnect resistance, which can degrade IC device performance—for instance, with increased resistance-capacitance (RC) delay. Accordingly, as ICs continue to scale down, further developments in processing and manufacturing are needed. For example, the conventional damascene approach faces substantial challenges when scaling down via dimensions. As vias become smaller, the proportion of high-resistance liner material within the via increases, leading to higher overall resistance that can degrade IC performance. Additionally, the conventional damascene process encounters difficulties with gap-fill at scaled via dimensions, resulting in defects and reduced yield. Moreover, the inability of the conventional damascene approach to adjust via size may cause reliability concerns for the connection between the via and the underlying line. Accordingly, although existing damascene processes have been generally adequate for their intended purposes, they have not been entirely satisfactory in all respects.

The present disclosure discloses embodiments of interconnect structures that provide low-resistance vias and metal lines thereon. Interconnect structures often include barrier layers. The barrier layer has the function of preventing the diffusion of the metal elements (such as copper) in the interconnect structures from diffusing into dielectric layers surrounding the interconnect structures, which is thus also referred to as a diffusion barrier layer. The barrier layer generally has a high resistivity, which increases contact resistance between the interconnect structures and underlying other conductive features (e.g., metal lines in a lower metal-layer level). In some embodiments of the present disclosure, the low-resistance interconnect structures include a dielectric barrier layer selectively formed on sidewalls of a via, but not formed under the bottom surface of the via. By not having a barrier layer directly contacting the underlying conductive features, contact resistance and thus the overall resistance of the interconnect structures can be reduced.

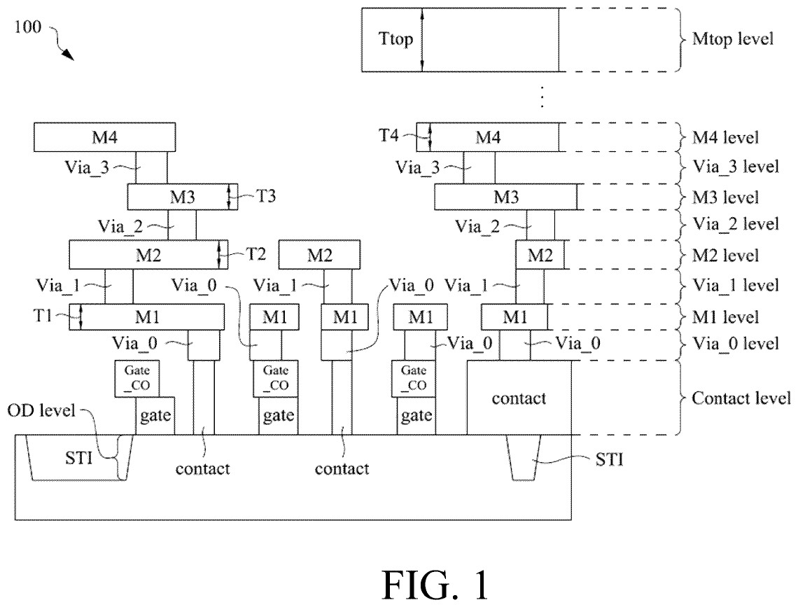

FIG. 1 illustrates a schematic cross-sectional view of a plurality of layers involved in a semiconductor device 100. It is noted that FIG. 1 is schematically illustrated to show various levels of interconnect structure and circuit device regions (e.g., transistors), and may not reflect the actual cross-sectional view of a semiconductor device 100. The interconnect structure includes a contact level, an OD (wherein the term “OD” represents “active region”) level, via levels Via_0 level, Via_1 level, Via_2 level, and Via_3 level, and metal-layer levels M1 level, M2 level, M3 level, M4 level . . . Mtop level. Each of the illustrated levels includes one or more dielectric layers and the conductive features formed therein. The conductive features that are at the same level may have top surfaces substantially level to each other, bottom surfaces substantially level to each other, and may be formed simultaneously. The contact level may include gate contacts (also referred to as contact plugs) for connecting gate electrodes of transistors to an overlying level such as the Via_0 level, and source/drain contacts (marked as “contact”) for connecting the source/drain regions of transistors to the overlying level. Thickness of the metal lines at the metal-layer levels M1 level, M2 level, M3 level, M4 level . . . Mtop level are denoted as T1, T2, T3, T4 . . . . Ttop, respectively. It is also noted that metal-lines at a higher level may have a larger thickness than metal lines at a lower level (i.e., T1<T2<T3<T4< . . . <Ttop). Further, metal lines at a higher level may have a larger pitch (e.g., center-to-center distance or edge-to-edge distance between adjacent metal lines) than metal lines at a lower level.

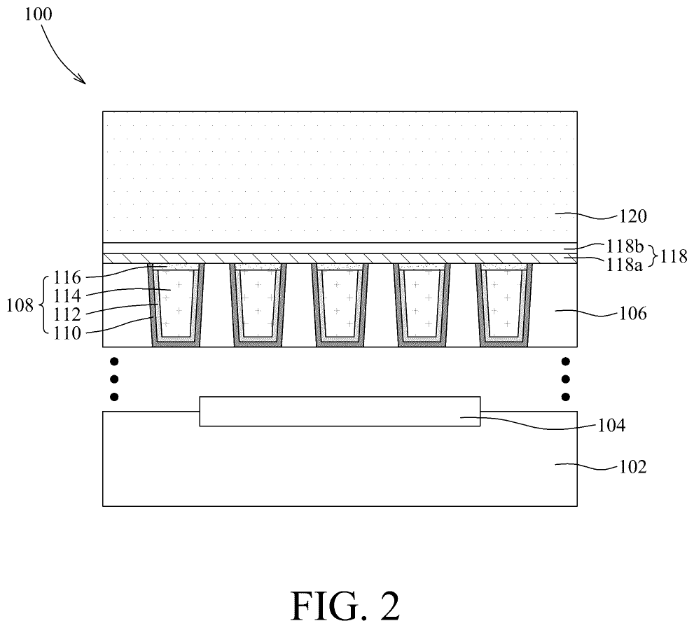

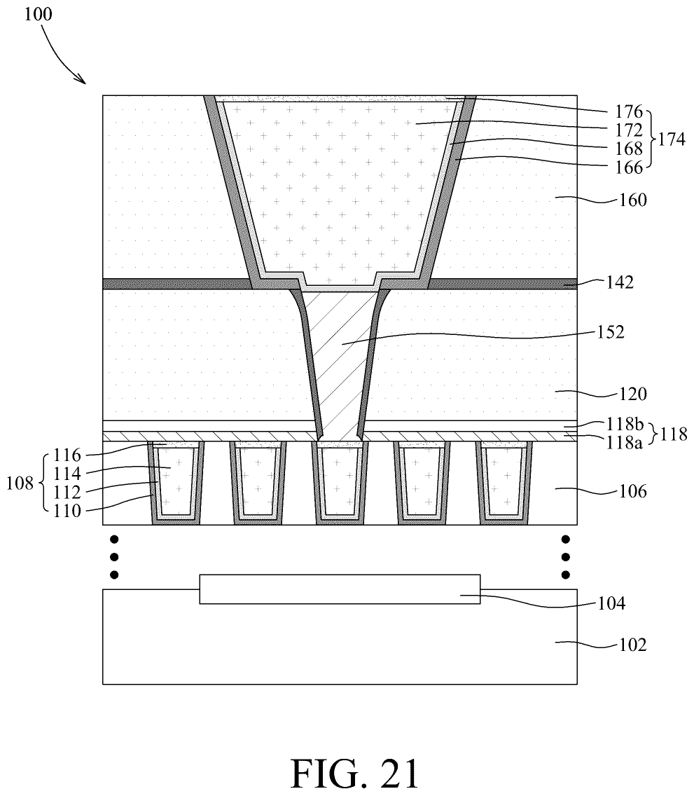

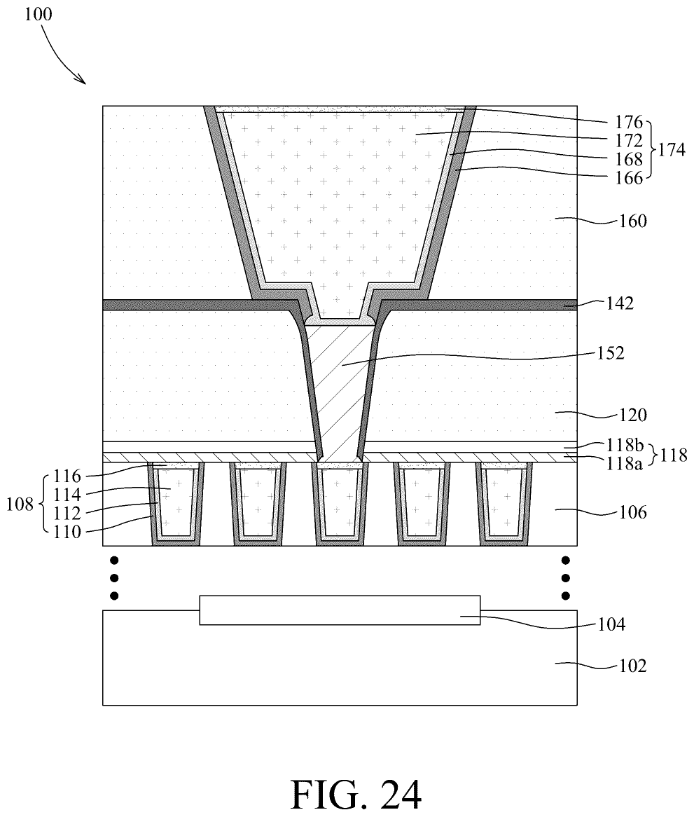

FIGS. 2 through 24 illustrate the cross-sectional views of intermediate stages in the formation of contact structures in the semiconductor device 100 in accordance with some embodiments of the present disclosure. Particularly, for the sake of simplicity, FIGS. 2 through 24 illustrate the cross-sectional views of intermediate stages in the formation of two consecutive metal-layer levels and the corresponding via level therebetween (e.g., a Mₓ level, a Via_x level, and a Mₓ₊₁ level, x representing an integer, or a Contact level, a Via_0 level, and a M₁ level) of the interconnect structure of the semiconductor device 100 in accordance with some embodiments.

FIG. 2 illustrates a cross-sectional view of the semiconductor device 100. In accordance with some embodiments of the present disclosure, the semiconductor device 100 is a device wafer including active devices such as transistors and/or diodes, and possibly passive devices such as capacitors, inductors, resistors, or the like. In accordance with alternative embodiments of the present disclosure, the semiconductor device 100 is an interposer wafer, which may or may not include active devices and/or passive devices. In accordance with yet alternative embodiments of the present disclosure, semiconductor device 100 is a package substrate strip, which may include package substrates with cores therein or core-less package substrates. In subsequent discussion, a device wafer is used as an example of the semiconductor device 100. The teaching of the present disclosure may also be applied to interposer wafers, package substrates, packages, etc.

In accordance with some embodiments of the present disclosure, the semiconductor device 100 includes a semiconductor substrate 102 and the features formed at a top surface of the semiconductor substrate 102. The semiconductor substrate 102 may comprise crystalline silicon, crystalline germanium, silicon germanium, a III-V compound semiconductor such as GaAsP, AlInAs, AlGaAs, GaInAs, GaInP, GaInAsP, or the like. The semiconductor substrate 102 may also be a bulk silicon substrate or a Silicon-On-Insulator (SOI) substrate. Shallow Trench Isolation (STI) regions (not shown in FIG. 2, but shown in FIG. 1) may be formed in the semiconductor substrate 102 to isolate the active regions in the semiconductor substrate 102. Although not shown, through-vias may be formed to extend into the semiconductor substrate 102, wherein the through-vias are used to electrically inter-couple the features on opposite sides of the semiconductor device 100.

In accordance with some embodiments of the present disclosure, circuit devices 104 are formed on the top surface of the semiconductor substrate 102. Examples of the circuit devices 104 include Complementary Metal-Oxide Semiconductor (CMOS) transistors, resistors, capacitors, diodes, or the like. The details of circuit devices 104 are not illustrated herein.

Further illustrated in FIG. 2 is a dielectric layer 106. The dielectric layer 106 may be an Inter-Layer Dielectric (ILD) layer or an Inter-Metal Dielectric (IMD) layer. In accordance with some embodiments of the present disclosure, the dielectric layer 106 is an ILD layer, in which contact plugs are formed. The corresponding dielectric layer 106 may be formed of Phospho Silicate Glass (PSG), Boro Silicate Glass (BSG), Boron-Doped Phospho Silicate Glass (BPSG), Fluorine-Doped Silicate Glass (FSG), a silicon oxide layer (formed using Tetra Ethyl Ortho Silicate (TEOS)), or the like. Dielectric layer 106 may be formed using spin-on coating, Chemical Vapor Deposition (CVD), Flowable Chemical Vapor Deposition (F-CVD), Plasma-Enhanced Chemical Vapor Deposition (PE-CVD), Low-Pressure Chemical Vapor Deposition (LP-CVD), or the like. In accordance with some embodiments of the present disclosure, the dielectric layer 106 is an IMD layer, in which metal lines and/or vias are formed. The corresponding dielectric layer 106 may be formed of a carbon-containing low-k dielectric material (e.g., organosilicate (SiOCH)), Hydrogen SilsesQuioxane (HSQ), MethylSilsesQuioxane (MSQ), or the like. In accordance with some embodiments of the present disclosure, the formation of the dielectric layer 106 includes depositing a porogen-containing dielectric material, and then performing a curing process to drive out the porogen, and hence the remaining dielectric layer 106 is porous.

One or more conductive features 108 are formed in the dielectric layer 106. The conductive feature 108 may be a metal line, a conductive via, a contact plug, or the like. In accordance with some embodiments, conductive feature 108 includes a barrier layer 110, a liner 112, a metal fill layer 114 over the liner 112, and a metal capping layer 116 over the metal fill layer 114. The barrier layer 110 may be formed of a conductive material, which is also referred to as a conductive barrier layer, such as titanium (Ti), titanium nitride (TiN), tantalum (Ta), tantalum nitride (TaN), or other suitable material that can block metal element diffusion, and may be deposited using Atomic Layer deposition (ALD), CVD, or physical vapor deposition (PVD) and may be formed to a thickness between about 0.5 nm and about 5 nm.

The liner 112 is deposited on the barrier layer 110. In some implementations, the liner 112 may be deposited using ALD, CVD, or PVD and may be formed to a thickness between about 0.5 nm and 3 nm. The liner 112 may be formed of suitable metal or metal alloy, such as cobalt (Co) or an alloy of cobalt and ruthenium (Ru). In one example, the liner 112 is made of Co. The liner 112 functions to increase adhesion between the metal fill layer 114 and the barrier layer 110. The liner 112 may also be referred to as an adhesive layer.

The metal fill layer 114 may be formed of copper (Cu), a copper alloy, aluminum (Al), or the like. The barrier layer 110 has the function of preventing the diffusion of the material (such as copper) in the metal fill layer 114 into the dielectric layer 106. In some embodiments, the metal fill layer 114 may be deposited using PVD, CVD, electroplating, electroless deposition, or other suitable deposition process. After the deposition of the metal fill layer 114, a planarization process such as a Chemical Mechanical Planarization (CMP) process or a mechanical polish process may be performed to remove excess portions of conductive material of the metal fill layer 114.

The metal capping layer 116 is deposited on the metal fill layer 114. In some embodiments, the CMP process performed prior in removing excess portions of the conductive material of the metal fill layer 114 also slightly recesses the top surfaces of the metal fill layer 114 and the liner 112. The metal capping layer 116 is deposited on the recessed top surfaces of the metal fill layer 114 and the liner 112. The barrier layer 110 may surround the metal capping layer 116 and separate the metal capping layer 116 from contacting the dielectric layer 106. In some other embodiments, the CMP process recesses the metal fill layer 114 but not the liner 112, such that the liner 112 may surround the metal capping layer 116 and separate the metal capping layer 116 from contacting the barrier layer 110. The metal capping layer 116 is formed of a conductive material such as cobalt (Co), molybdenum (Mo), ruthenium (Ru), or other suitable conductive material. In furtherance of some embodiments, the metal capping layer 116 and the liner 112 may have the same material composition. For example, both the metal capping layer 116 and the liner 112 may be formed of Co. In some other embodiments, the metal capping layer 116 and the liner 112 may include different material compositions. For example, the liner 112 may be formed of Co, and the metal capping layer 116 may be formed of Ru. In some embodiments, the metal capping layer 116 is thinner than the liner 112. Alternatively, the metal capping layer 116 may have the same thickness or thicker than the liner 112.

As also shown in FIG. 2, an etch stop layer 118 is formed over the dielectric layer 106 and the conductive features 108. The etch stop layer 118 has a high etching selectivity with relative to the overlying dielectric layer 120, and hence the etch stop layer 118 may be used to stop the etching of the dielectric layer 120. In some embodiments, the etch stop layer 118 may be deposited using ALD, plasma-enhanced ALD (PE-ALD), CVD, PE-CVD, or other suitable deposition process. The etch stop layer 118 may be a single layer structure or a multilayered structure. In the depicted embodiment, the etch stop layer 118 is a two-layer structure including a first sub-layer 118a and a second sub-layer 118b. The first sub-layer 118a and the second sub-layer 118b include different material compositions, such as an oxide and a nitride. In accordance with some embodiments of the present disclosure, each sub-layer of the etch stop layer 118 may be formed of a dielectric material such as but not limited to, an oxide, carbide, nitride, oxycarbide, oxynitride, carbonitride, or oxycarbonitride of combinations of aluminum, titanium, silicon, zirconium, yttrium, and hafnium. For example, each sub-layer of the etch stop layer 118 may be formed from one of aluminum oxide, aluminum carbide, aluminum nitride, aluminum oxycarbide, aluminum oxynitride aluminum carbonitride, aluminum oxycarbonitride, titanium oxide, titanium carbide, titanium nitride titanium oxycarbide, titanium oxynitride, titanium carbonitride, titanium oxycarbonitride, silicon oxide, silicon carbide, silicon nitride, silicon oxycarbide, silicon oxynitride, silicon carbonitride, silicon oxycarbonitride, zirconium oxide, zirconium carbide, zirconium nitride zirconium oxycarbide, zirconium oxynitride, zirconium carbonitride, zirconium oxycarbonitride, yttrium oxide, yttrium carbide, yttrium nitride, yttrium oxycarbide, yttrium oxynitride, yttrium carbonitride, yttrium oxycarbonitride, hafnium oxide, hafnium carbide, hafnium nitride, hafnium oxycarbide, hafnium oxynitride, hafnium carbonitride, and hafnium oxycarbonitride. In various embodiments, the etch stop layer 118 may have a thickness ranging from about 30 Å to about 100 Å. This range is not trivial or arbitrary. If the thickness of the etch stop layer 118 is less than about 30 Å, the underlying conductive features 108 (e.g., metal lines) may be oxidized. If the thickness of the etch stop layer 118 is larger than about 100 Å, a thickness of a dielectric layer disposed on the etch stop layer 118 may be decreased, which may adversely affect performance of the interconnect structure.

A dielectric layer 120 is formed over the etch stop layer 118. In accordance with some embodiments, the dielectric layer 120 is an IMD layer or an ILD layer. The corresponding dielectric layer 120 may be formed of PSG, BSG, BPSG, FSG, TEOS oxide, HSQ, MSQ, or the like. In accordance with some embodiments of the present disclosure, the dielectric layer 120 may be formed of a carbon-containing low-k dielectric material (e.g., organosilicate (SiOCH)). The dielectric layer 120 may be formed using spin-on coating, CVD, F-CVD, PE-CVD, LP-CVD, or the like. In some embodiments, the formation of the dielectric layer 120 includes depositing a porogen-containing dielectric material, and then performing a curing process to drive out the porogen, and hence the remaining dielectric layer 120 is porous.

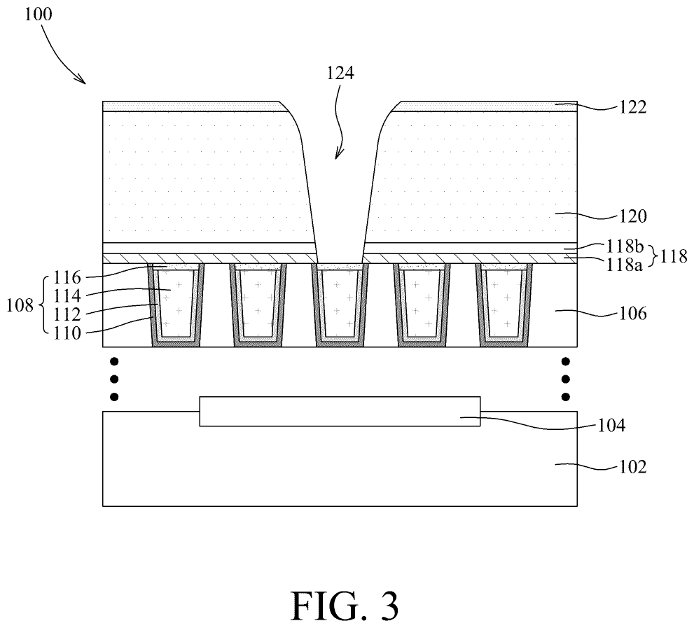

As shown in FIG. 3, a via opening 124 is formed through etching. The via opening 124 may be formed, for example, by photolithography techniques, using the patterned hard mask 122 as an etching mask. In accordance with some embodiments of the present disclosure, the etching of the dielectric layer 120 is performed using a process gas comprising fluorine and carbon, wherein fluorine is used for etching, with carbon having the effect of protecting the sidewalls of the resulting opening. With an appropriate fluorine and carbon ratio, the via opening 124 may have a desirable profile. For example, the process gases for the etching include a fluorine and carbon-containing gas(es) such as C₄F₈, CH₂F₂, and/or CF₄, and a carrier gas such as N₂. In an example of the etching process, the flow rate of C₄F₈ is in the range between about 0 sccm and about 50 sccm, the flow rate of CF₄ is in the range between about 0 sccm and about 300 sccm (with at least one of C₄F₈ having a non-zero flow rate), and the flow rate of N₂ is in the range between about 0 sccm and about 200 sccm. In accordance with alternative embodiments, the process gases for the etching include CH₂F₂ and a carrier gas such as N₂. In an example of the etching process, the flow rate of CH₂F₂ is in the range between about 10 sccm and about 200 sccm, and the flow rate of N₂ is in the range between about 50 sccm and about 100 sccm. During the etching process, the semiconductor device 100 may be kept at a temperature in the range between about 30° C. and about 60° C. In the etching process, plasma may be generated from the etching gases. The Radio Frequency (RF) power of the power source for the etching may be lower than about 700 Watts, and the pressure of the process gases is in the range from about 15 mTorr and about 30 mTorr. The etch stop layer 118 is subsequently etched with a suitable etchant, and the metal capping layer 116 is exposed at the bottom of the via opening 124. Extending the via opening 124 through the dielectric layer 120 and further extending the via opening 124 through the etch stop layer 118 are performed in separate photo lithography processes. For example, in a first photo lithography process, the via opening 124 is extended through the dielectric layer 120; in a second lithography process, the via opening 124 is extended through the etch stop layer 118. The pattern hard mask 122 may be consumed during the lithography processes or removed in a separate etching process.

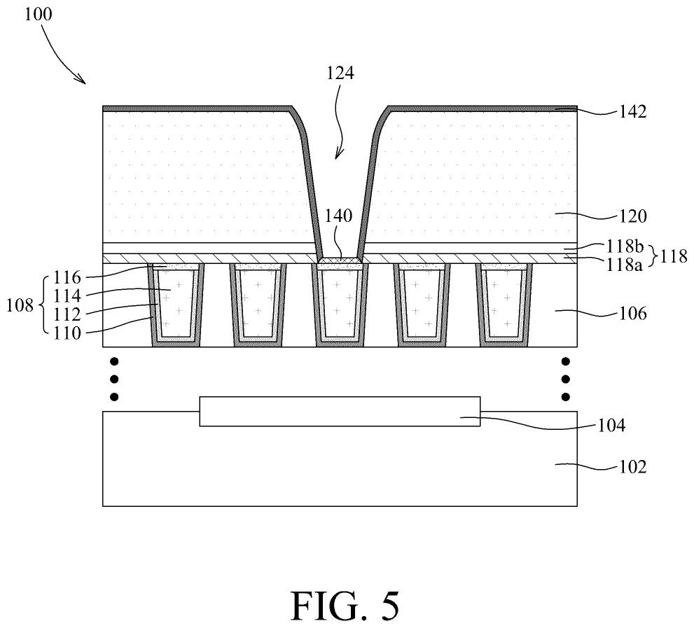

Next, referring to FIG. 5, inhibitor film 140 is selectively formed on the exposed top surface of the metal capping layer 116, but not on sidewalls of the via opening 124. The inhibitor film 140 may be deposited by ALD, CVD, spin-on coating, or other suitable deposition process. In some embodiments, the selective deposition of the inhibitor film 140 is enabled by a selective self-assembled-monolayer (SAM) process. In some embodiments, the selective SAM process is a vapor phase or a liquid phase process that forms one or more monolayers of molecules of SAM material on the surface of the metal capping layer 116. A thickness of the inhibitor film 140 may be less than about 20 Å, which is less than a thickness of the etch stop layer 118 or even less than a thickness of the sub-layer 118b of the etch stop layer 118. In some embodiments, the SAM material includes an organo-silane or an organo-phosphane, such as octadecyltrichlorosilane (ODTS), octadecyltrimethoxysilane (OTMS), and (3-Aminopropyl)triethoxysilane (APTMS). In some embodiments, the inhibitor film 140 is formed of thiol, 4,4′-Oxydiphthalic Anhydride (ODPA), or a polymer containing silicon, carbon, nitrogen, oxygen. The inhibitor film 140 acts as an inhibitor to subsequent via barrier deposition process. Due to the existence of the selective SAM material, a via barrier deposition is inhibited on the surface of conducting material. As a result, minimal or no via barrier layer would be formed on the exposed top surface of the metal capping layer 116. Notably, since the selective deposition process also prohibits the inhibitor film 140 from growing on dielectric sidewalls of the etch stop layer 118, a gap 126 with a tip at the bottom and a tapering opening on the top still exists between the edge of the inhibitor film 140 and the sidewall of the etch stop layer 118, such that a bottom portion of the sidewall of the etch stop layer 118 remains exposed in the gap 126.

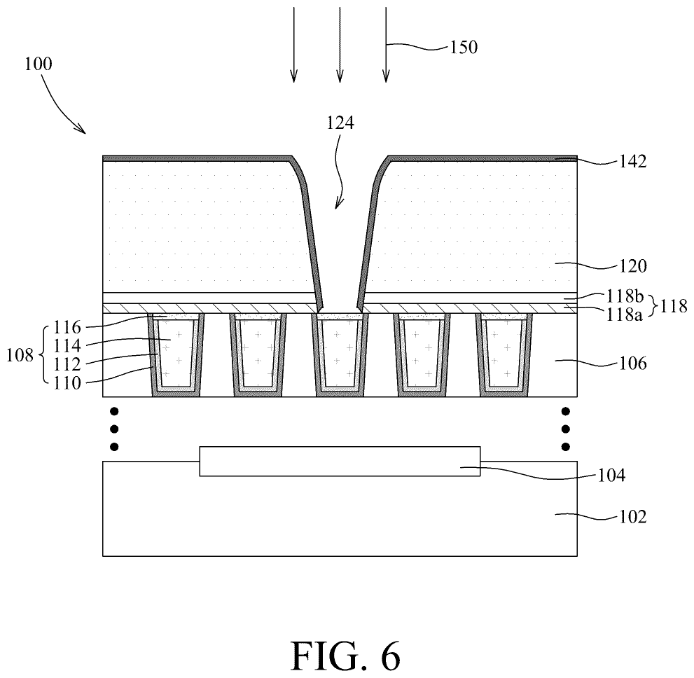

Next, referring to FIG. 6, a barrier layer 142 is deposited lining the via opening 124 and also cover the top surface of the dielectric layer 120. The barrier layer 142 functions to prevent subsequently deposited metallic material (as to form a contact via) from diffusing into the dielectric layer 120. The barrier layer 142 may be deposited using ALD, PE-ALD, CVD, PE-CVD, or another suitable deposition process. The inhibitor film 140 blocks the growth of the barrier layer 142 at the bottom of the via opening 124. Without the barrier layer 142 on the bottom surface of the via opening 124, a subsequently formed contact via can directly contact the metal capping layer 116, resulting in reduced contact resistance. Also, because there is no need for conduction from the barrier layer 142 as not between the contact via and the metal capping layer 116, unlike the conductive barrier layer 110, the barrier layer 142 may be formed of a dielectric material. The barrier layer 142 may also be referred to as a dielectric barrier layer. Employing a dielectric material for the barrier layer 142 may also facilitate adhesion of the subsequently deposited metallic material to the sidewalls of the via opening 124. Therefore, a liner layer or an adhesive layer may be omitted, which enlarges the volume of the metal fill layer of the via and further helps reduce overall resistance. In accordance with some embodiments of the present disclosure, the barrier layer 142 may be formed of a dielectric material such as but not limited to, an oxide, carbide, nitride, oxycarbide, oxynitride, carbonitride, or oxycarbonitride of combinations of aluminum, silicon, zirconium, yttrium, and hafnium. For example, the barrier layer 142 may be formed from one of aluminum oxide, aluminum carbide, aluminum nitride, aluminum oxycarbide, aluminum oxynitride, aluminum carbonitride, aluminum oxycarbonitride, silicon oxide, silicon carbide, silicon nitride, silicon oxycarbide, silicon oxynitride, silicon carbonitride, silicon oxycarbonitride, zirconium oxide, zirconium carbide, zirconium nitride, zirconium oxycarbide, zirconium oxynitride, zirconium carbonitride, zirconium oxycarbonitride, yttrium oxide, yttrium carbide, yttrium nitride, yttrium oxycarbide, yttrium oxynitride, yttrium carbonitride, yttrium oxycarbonitride, hafnium oxide, hafnium carbide, hafnium nitride, hafnium oxycarbide, hafnium oxynitride, hafnium carbonitride, and hafnium oxycarbonitride.

In some embodiments, the dielectric barrier layer 142 is conformally deposited. Herein, the term “conformal” or “conformally” is used to describe that a material is formed with substantially uniform thickness over various exposed surface of the semiconductor device 100. In some other embodiments, the dielectric barrier layer 142 is non-conformal, such as with a larger thickness for its horizontal portion (e.g., on the top surface of the dielectric layer 120) and a smaller thickness for its vertical portion (e.g., on the sidewalls of the via opening 124). In various embodiments, the thinnest portion of the dielectric barrier layer 142 is the tip filling the gap 126 between the edge of the inhibitor film 140 and the sidewall of the etch stop layer 118. Other than the tip, a thickness of the dielectric barrier layer 142 over the sidewalls of the via opening 124 range from about 5 Å to about 25 Å. This range is not trivial or arbitrary. If the thickness of the dielectric barrier layer 142 is less than about 5 Å, the dielectric barrier layer 142 may have a poor formation, and cannot efficiently prevent metal ions of the contact via and halide anions (derived from a precursor material for forming the contact via) from diffusing into the dielectric layer 120. If the thickness of the dielectric barrier layer 142 is larger than about 25 Å, it may adversely affect the size of the contact via or the contact via layer, and result in an increased capacitance between two metal lines disposed in two dielectric layers.

Referring to FIG. 6, a post-deposition treatment 150 is performed to remove the inhibitor film 140. The post-deposition treatment 150 may be performed through a thermal treatment, an ultraviolet (UV) treatment, or a plasma treatment. In some embodiments, the post-deposition treatment 150 is a plasma treatment that includes applying a mixture of a process gas of hydrogen and a carrier gas of argon. During the plasma treatment, the temperature of the semiconductor device 100 may be higher than about 200° C., for example, in the range between about 200° C. and about 300° C. The treatment duration may be in the range between about 30 seconds and about 60 seconds. The plasma treatment is also referred to as a plasma de-blocking treatment. As a result of the post-deposition treatment 150, the inhibitor film 140 is removed. In the post-deposition treatment 150, the inhibitor film 140 is decomposed into gases, which are removed. With the inhibitor film 48 being removed, the top surface of the metal capping layer 116 is exposed in the via opening 124.

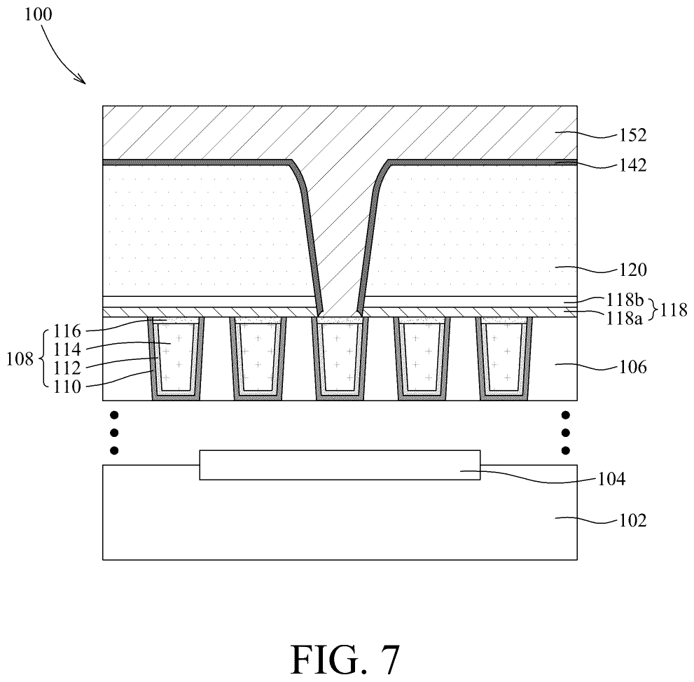

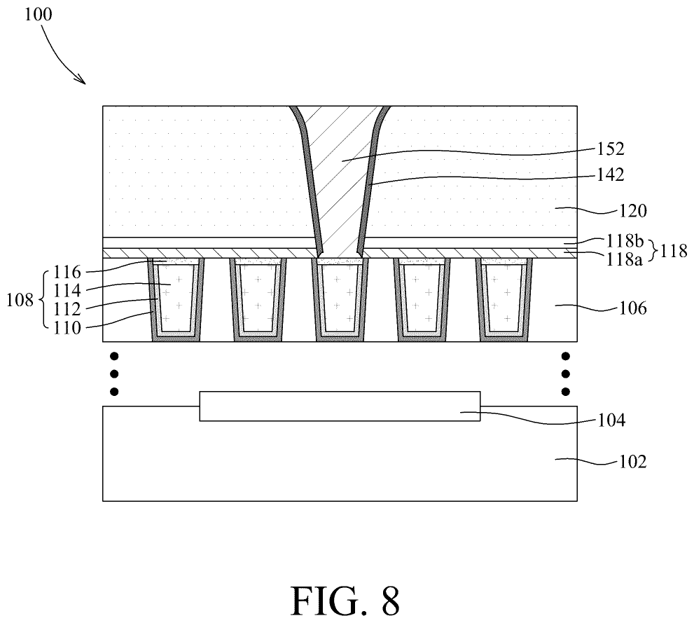

Referring to FIG. 7, a conductive material 152 is deposited to fill the via opening 124. The conductive material 152 may be copper. Alternatively, the conductive material 152 may be a metal other than copper, such as ruthenium, molybdenum, tungsten, or other suitable low resistance metal. In some embodiments, the conductive material 152 may be deposited using PVD, CVD, PE-CVD, ALD, PE-ALD, electroplating, electroless deposition, or other suitable deposition process. After the deposition of the conductive material 152, a planarization process such as a CMP process or a mechanical polish process may be performed to remove excess portions of conductive material 152 and horizontal portions of the dielectric barrier layer 142, hence forming a contact via 152 in the via opening 124, as shown in FIG. 8. The contact via 152 directly lands on the metal capping layer 116 of the underlying conductive feature 108 with no barrier layer therebetween. The bottom portion of the contact via 152 may inherit the shape of the inhibitor film 140 with an expanded footing profile, such that the smallest width of the contact via 152 may be located slightly above the bottom surface but under the top surface of the etch stop layer 118, or even under the top surface of the sub-layer 118a of the etch stop layer 118.

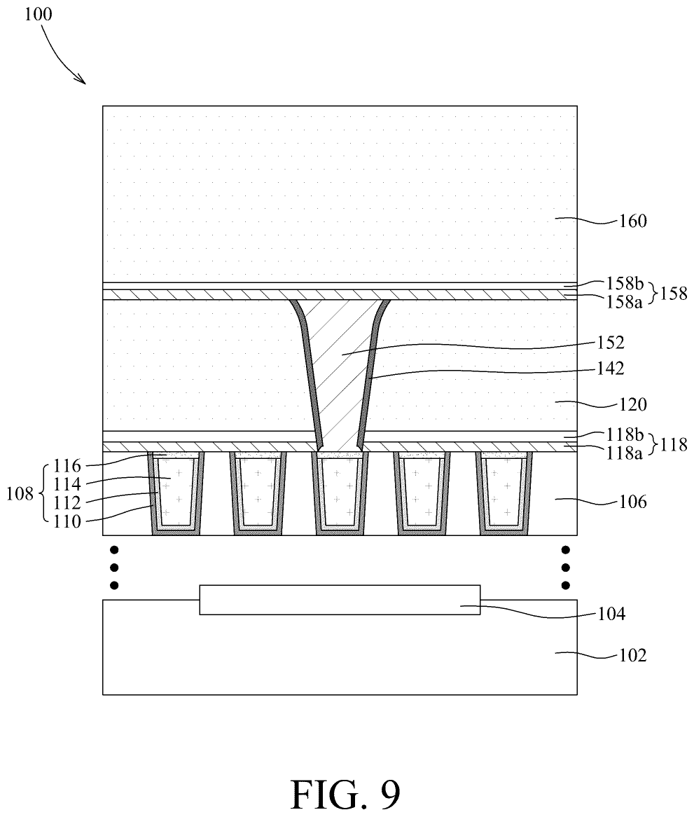

Now, referring to FIG. 9, an etch stop layer 158 and a dielectric layer 160 are sequentially formed over the contact via 152 and the dielectric layer 120. The etch stop layer 158 has a high etching selectivity with relative to the overlying dielectric layer 160, and hence the etch stop layer 158 may be used to stop the etching of the dielectric layer 160. In some embodiments, the etch stop layer 158 may be deposited using ALD, plasma-enhanced ALD (PE-ALD), CVD, PE-CVD, or other suitable deposition process. The etch stop layer 158 may be a single layer structure or a multilayered structure. In the depicted embodiment, the etch stop layer 158 is a two-layer structure including a first sub-layer 158a and a second sub-layer 158b. The first sub-layer 158a and the second sub-layer 158b include different material compositions, such as an oxide and a nitride. In some embodiments, the material compositions of the etch stop layer 158 is similar to the etch stop layer 118. The dielectric layer 160 is formed over the etch stop layer 158. In accordance with some embodiments, the dielectric layer 160 is an IMD layer or an ILD layer. The dielectric layer 160 may be formed using spin-on coating, CVD, F-CVD, PE-CVD, LP-CVD, or the like. In some embodiments, the material compositions of the dielectric layer 160 is similar to the dielectric layer 120. In some embodiments, the formation of the dielectric layer 160 includes depositing a porogen-containing dielectric material, and then performing a curing process to drive out the porogen, and hence the remaining dielectric layer 160 is porous.

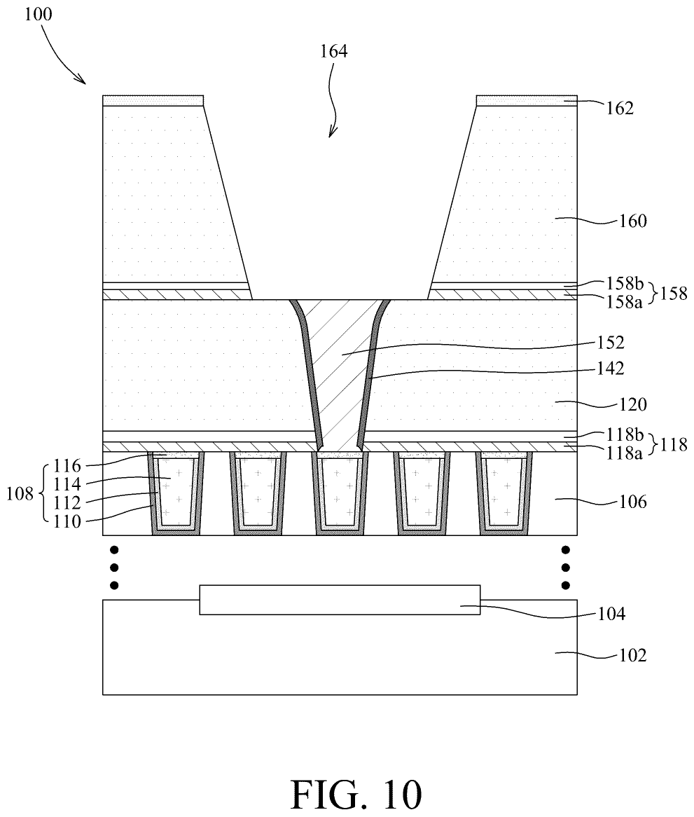

As shown in FIG. 10, a trench 164 is formed through etching. The trench 164 may be formed, for example, by photolithography techniques, using the patterned hard mask 162 as an etching mask. In accordance with some embodiments of the present disclosure, the etching of the dielectric layer 160 is performed using a process gas comprising fluorine and carbon, wherein fluorine is used for etching, with carbon having the effect of protecting the sidewalls of the resulting opening. With an appropriate fluorine and carbon ratio, the trench 164 may have a desirable profile. For example, the process gases for the etching include a fluorine and carbon-containing gas(es) such as C₄F₈, CH₂F₂, and/or CF₄, and a carrier gas such as N₂. In an example of the etching process, the flow rate of C₄F₈ is in the range between about 0 sccm and about 50 sccm, the flow rate of CF₄ is in the range between about 0 sccm and about 300 sccm (with at least one of C₄F₈ having a non-zero flow rate), and the flow rate of N₂ is in the range between about 0 sccm and about 200 sccm. In accordance with alternative embodiments, the process gases for the etching include CH₂F₂ and a carrier gas such as N₂. In an example of the etching process, the flow rate of CH₂F₂ is in the range between about 10 sccm and about 200 sccm, and the flow rate of N₂ is in the range between about 50 sccm and about 100 sccm. During the etching process, the semiconductor device 100 may be kept at a temperature in the range between about 30° C. and about 60° C. In the etching process, plasma may be generated from the etching gases. The RF power of the power source for the etching may be lower than about 700 Watts, and the pressure of the process gases is in the range from about 15 mTorr and about 30 mTorr. The etch stop layer 158 is subsequently etched with a suitable etchant, and the contact via 152 and the dielectric barrier layer 142 is exposed at the bottom of the trench 164. Extending the trench 164 through the dielectric layer 160 and further extending the trench 164 through the etch stop layer 158 are performed in separate photo lithography processes. For example, in a first photo lithography process, the trench 164 is extended through the dielectric layer 160; in a second lithography process, the trench 164 is extended through the etch stop layer 158. The pattern hard mask 162 may be consumed during the lithography processes or removed in a separate etching process.

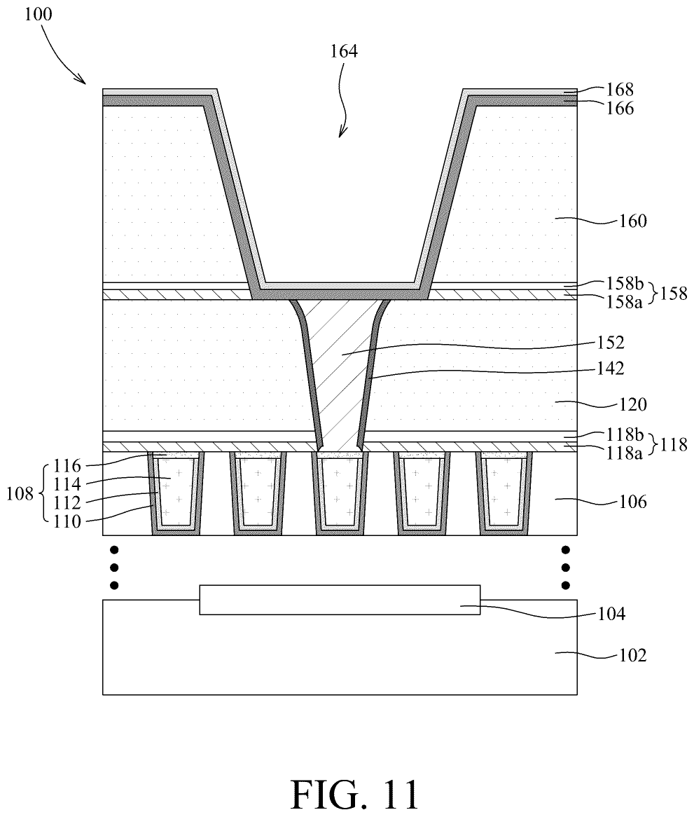

Referring to FIG. 11, a barrier layer 166 is conformally deposited on exposed surfaces of the semiconductor device 100 and a liner 168 is conformally deposited on the barrier layer 166. The barrier layer 166 may be formed of a conductive material, which is also referred to as a conductive barrier layer, such as titanium (Ti), titanium nitride (TiN), tantalum (Ta), tantalum nitride (TaN), or other suitable material that can block metal element diffusion, and may be deposited using Atomic Layer deposition (ALD), CVD, or physical vapor deposition (PVD) and may be formed to a thickness between about 0.5 nm and about 5 nm. The barrier layer 166 covers the exposed top surface of the contact via 152. The liner 168 is conformally deposited on the barrier layer 166. In some implementations, the liner 168 may be deposited using ALD, CVD, or PVD and may be formed to a thickness between about 0.5 nm and 3 nm. The liner 168 may be formed of suitable metal or metal alloy, such as cobalt (Co) or an alloy of cobalt and ruthenium (Ru). In one example, the liner 168 is made of Co. The liner 168 functions to increase adhesion between the subsequently-deposited metal fill layer and the barrier layer 166. The liner 168 may also be referred to as an adhesive layer.

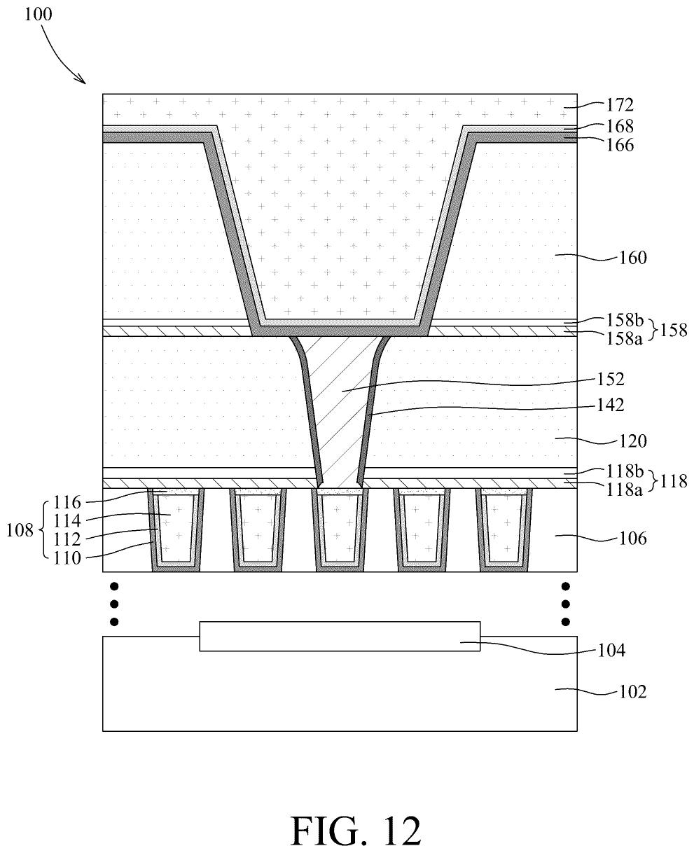

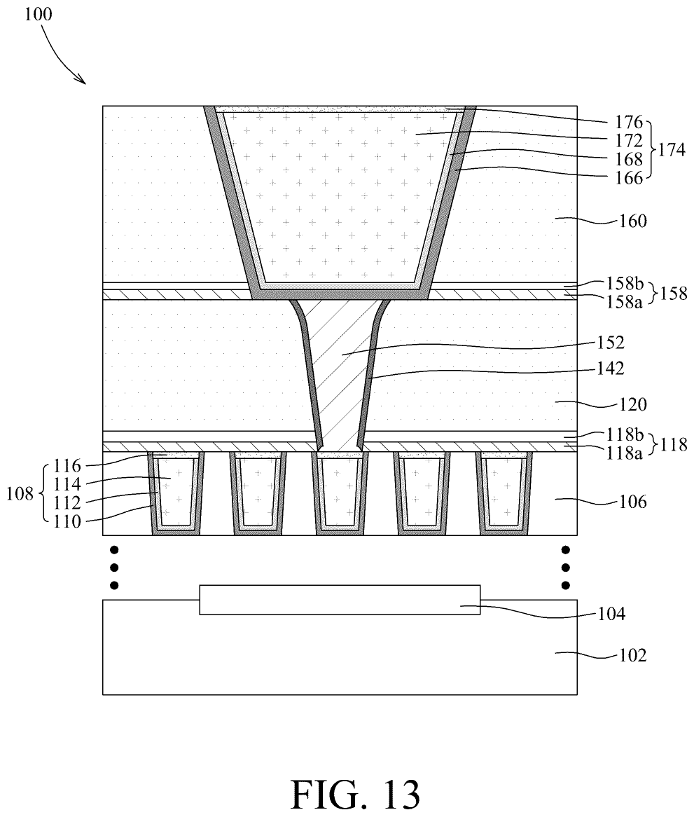

Referring to FIG. 12, a conductive material 172 is deposited to fill the trench 164. The conductive material 172 is also referred to as a metal fill layer. The conductive material 172 may be copper. Alternatively, the conductive material 172 may be a metal other than copper, such as ruthenium, molybdenum, tungsten, or other suitable low resistance metal. In some embodiments, the conductive material 172 may be deposited using PVD, CVD, PE-CVD, ALD, PE-ALD, electroplating, electroless deposition, or other suitable deposition process. After the deposition of the conductive material 172, a planarization process such as a CMP process or a mechanical polish process may be performed to remove excess portions of conductive material 172 (as resulting in a metal fill layer 172) and horizontal portions of the liner 168 and barrier layer 166, hence forming a metal line 174 in the trench 164, as shown in FIG. 13. The metal line 174 includes the barrier layer 166, the liner 168, the metal fill layer 172, and a metal capping layer 176.

FIG. 13 also illustrates the formation of the metal capping layer 176, as a top portion of the metal line 174. The metal capping layer 176 is deposited on the metal fill layer 172. In some embodiments, the CMP process performed prior in removing excess portions of the conductive material of the metal fill layer 172 also slightly recesses the top surfaces of the metal fill layer 172 and the liner 168. The metal capping layer 176 is deposited on the recessed top surfaces of the metal fill layer 172 and the liner 168. The barrier layer 166 may surround the metal capping layer 176 and separate the metal capping layer 176 from contacting the dielectric layer 160. In some other embodiments, the CMP process recesses the metal fill layer 172 but not the liner 168, such that the liner 168 may surround the metal capping layer 176 and separate the metal capping layer 176 from contacting the barrier layer 166. The metal capping layer 176 is formed of a conductive material such as cobalt (Co), molybdenum (Mo), ruthenium (Ru), or other suitable conductive material. In furtherance of some embodiments, the metal capping layer 176 and the liner 168 may have the same material composition. For example, both the metal capping layer 176 and the liner 168 may be formed of Co. In some other embodiments, the metal capping layer 176 and the liner 168 may include different material compositions. For example, the liner 168 may be formed of Co, and the metal capping layer 176 may be formed of Ru. In some embodiments, the metal capping layer 176 is thinner than the liner 168. Alternatively, the metal capping layer 176 may have the same thickness or thicker than the liner 168.

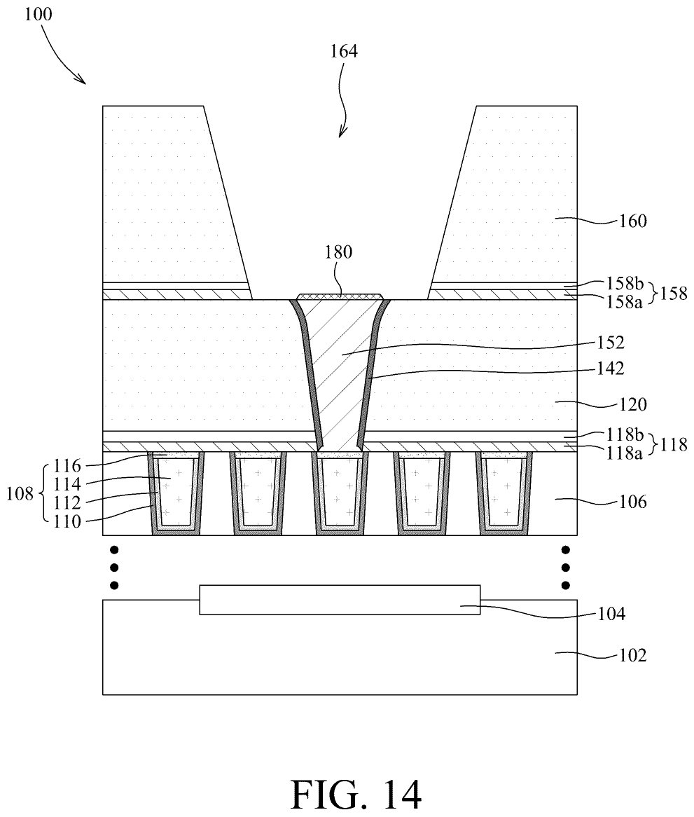

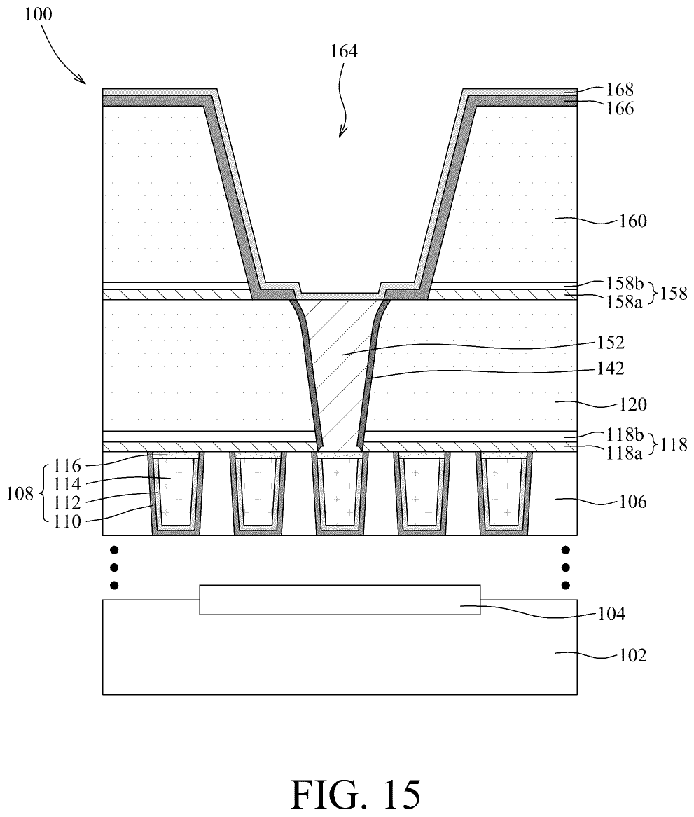

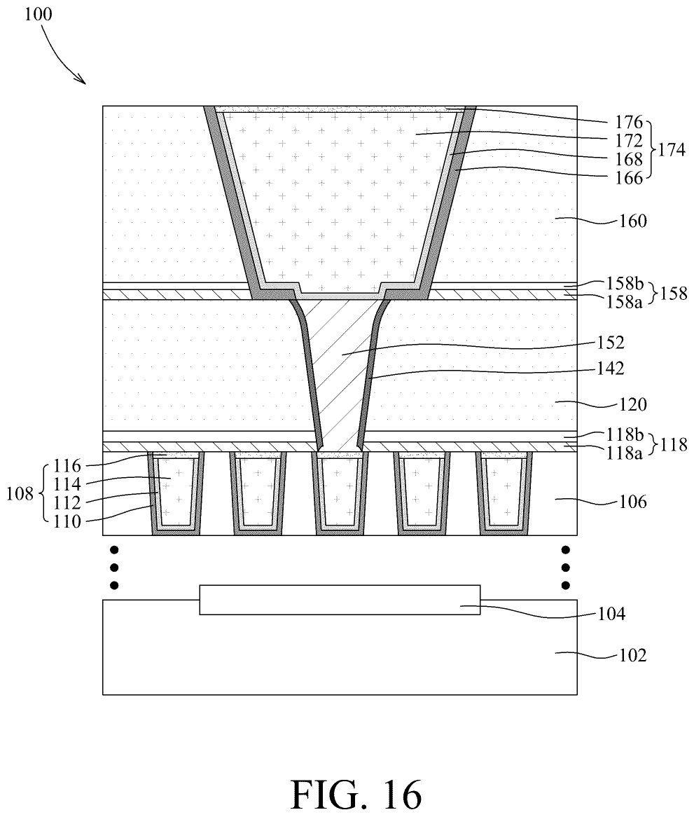

In the depicted embodiment of the semiconductor device 100 as shown in FIG. 13, the barrier layer 166 covers the top surface of the contact via 152. FIGS. 14-16 illustrate an alternative embodiment. Referring to FIG. 14, after the structure in FIG. 10 is derived, an inhibitor film 180 is selectively formed on the exposed top surface of the contact via 152, but not on dielectric surfaces of the sidewalls of the trench 164 and the top surface of the dielectric barrier layer 142. The inhibitor film 180 may be deposited by ALD, CVD, spin-on coating, or other suitable deposition process. The material composition of the inhibitor film 180 may be similar to the inhibitor film 140 as discussed above. A thickness of the inhibitor film 140 may be less than about 20 Å, which is less than a thickness of the etch stop layer 158 or even less than a thickness of the sub-layer 158b of the etch stop layer 158. The inhibitor film 180 acts as an inhibitor to subsequent via barrier deposition process. Referring to FIG. 15, due to the existence of the inhibitor film 180, a barrier deposition is inhibited on the surface of conducting material. As a result, no barrier layer 166 is formed on the exposed top surface of the contact via 152. After the barrier layer 166 conformally lines the sidewalls of the trench 164 and the exposed top surfaces of the dielectric layer 120 and the dielectric barrier layer 142, the inhibitor film 180 is removed in a post-deposition treatment similar to the post-deposition treatment 150 as discussed above. After the top surface of the contact via 152 is exposed, the liner 168 is conformally deposited on the barrier layer 166 and covers the top surface of the contact via 152. Referring to FIG. 16, the metal fill layer 172 and the metal capping layer 176 are sequentially deposited in the trench 164 to complete the formation of the metal line 174. As shown in FIG. 16, the top surface of the contact via 152 is covered by the liner 168 instead of the barrier layer 166. Depending on the thickness of the liner 168, the bottom surface of the metal fill layer 172 may be lower than a top surface of the horizontal portion of the barrier layer 166.

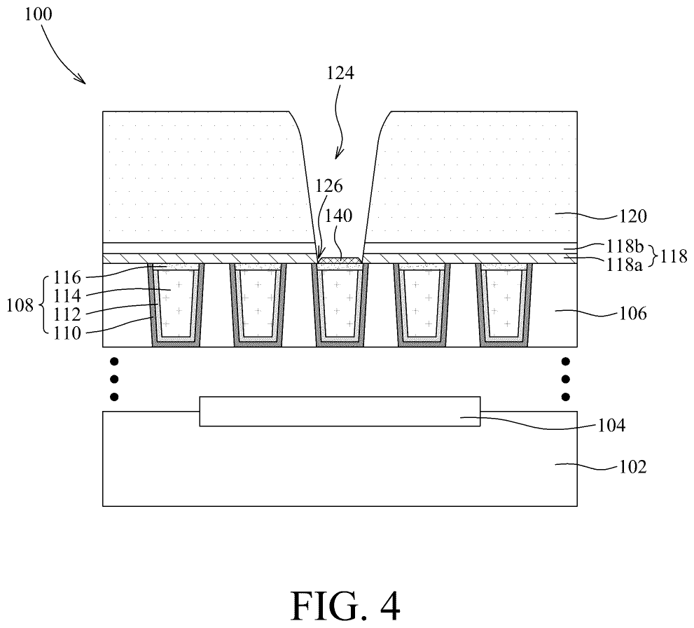

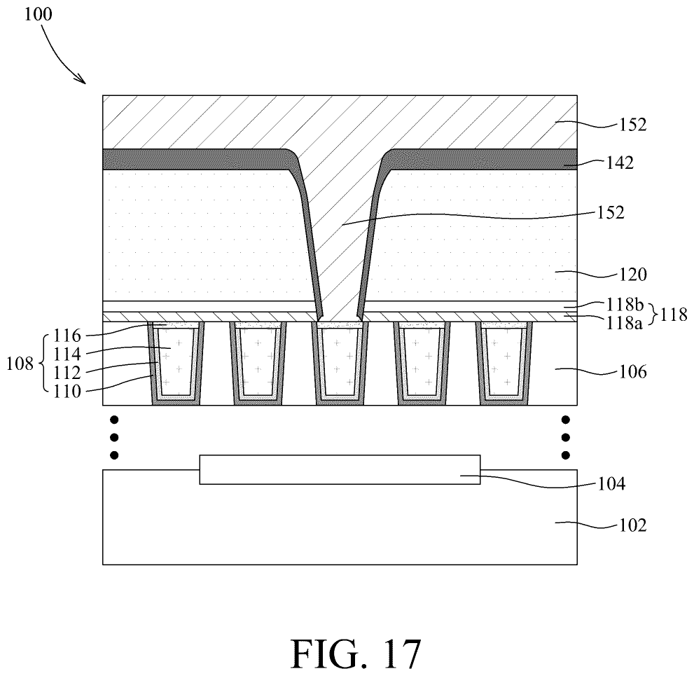

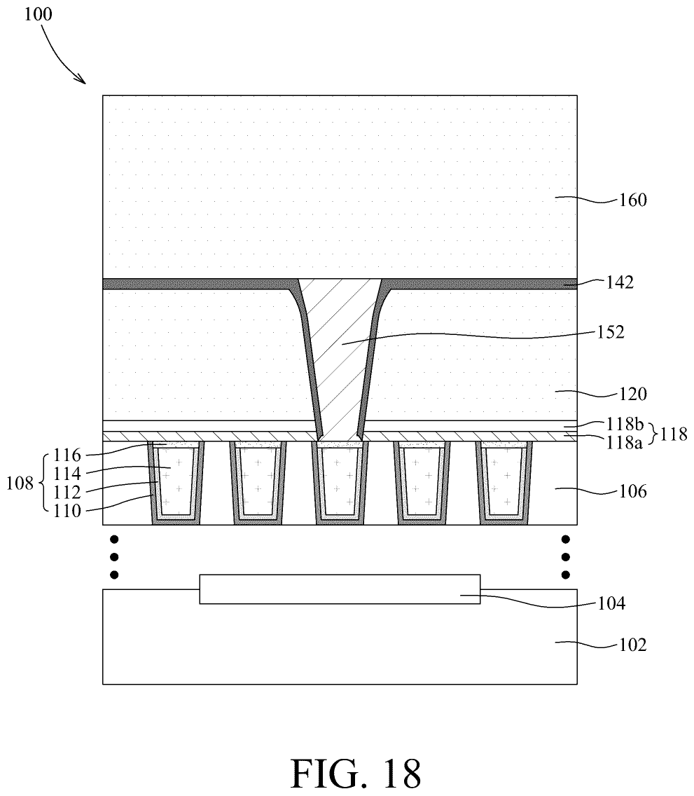

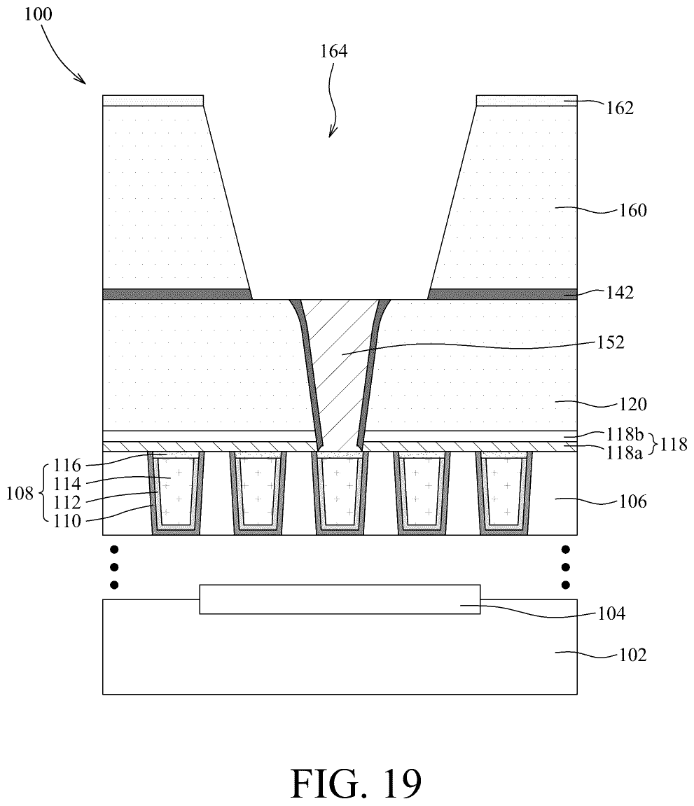

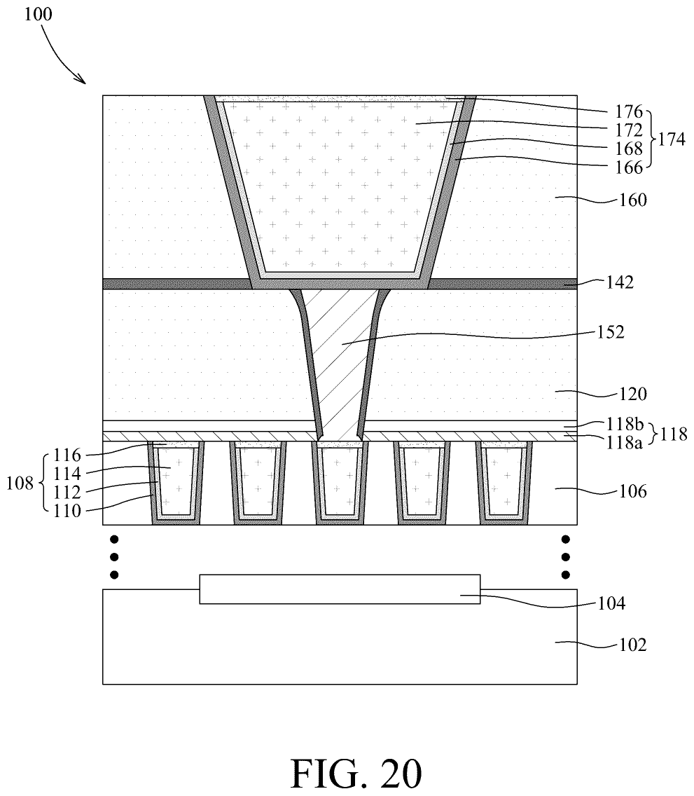

FIGS. 17-20 illustrate an alternative embodiment. Referring to FIG. 17, after the structure in FIG. 4 is derived, the dielectric barrier layer 142 and the conductive material 152 are sequentially deposited prior to and after the removal of the inhibitor film 140, respectively. One difference is that the dielectric barrier layer 142 is not conformally deposited but with the horizontal portion covering the top surface of the dielectric layer 120 thicker than the vertical portion covering the sidewalls of the via opening 124. This may be due to the relatively more open area available at the top surface of the dielectric layer 120 to facilitate the accumulation of dielectric material during the deposition process. Referring to FIG. 18, the horizontal portion of the dielectric barrier layer 142 remains on the top surface of the dielectric layer 120 after the planarization process due to its relatively larger thickness. Since the horizontal portion of the dielectric barrier layer 142 may function as an etch stop layer, the dielectric layer 160 is directly deposited on the horizontal portion of the dielectric barrier layer 142 and the top surface of the contact via 152. Referring to FIG. 19, during the formation of the trench 164, a portion of the horizontal portion of the dielectric barrier layer 142 exposed in the trench 164 is also removed, such that the top surface of the dielectric layer 120 is exposed in the trench 164. In other words, the horizontal portion of the dielectric barrier layer 142 is disconnected from its vertical portion. Referring to FIG. 20, the metal line 174 is formed in the trench 164. As shown in FIG. 20, the barrier layer 166 lines the sidewalls and the bottom surface of the trench 164, and the horizontal portion of the barrier layer 166 covers the top surfaces of the dielectric layer 120, the dielectric barrier layer 142, and the contact via 152. Depending on the thickness of the horizontal portion of the dielectric barrier layer 142, the top surface of the horizontal portion of the dielectric barrier layer 142 may be above, level, or lower than the top surface of the horizontal portion of the barrier layer 166.

Similar to the alternative embodiment as depicted in FIGS. 14-16, FIG. 21 illustrates an alternative embodiment of the resultant structure in FIG. 20, in which the top surface of the contact via 152 is covered by the liner 168 instead of the barrier layer 166. No barrier layer 166 is formed on the exposed top surface of the contact via 152 due to an inhibitor film deposited on the exposed metal surface that inhibits the barrier deposition. Depending on the thickness of the liner 168, the bottom surface of the metal fill layer 172 may be lower than a top surface of the horizontal portion of the barrier layer 166, and/or even lower than a top surface of the horizontal portion of the dielectric barrier layer 142.

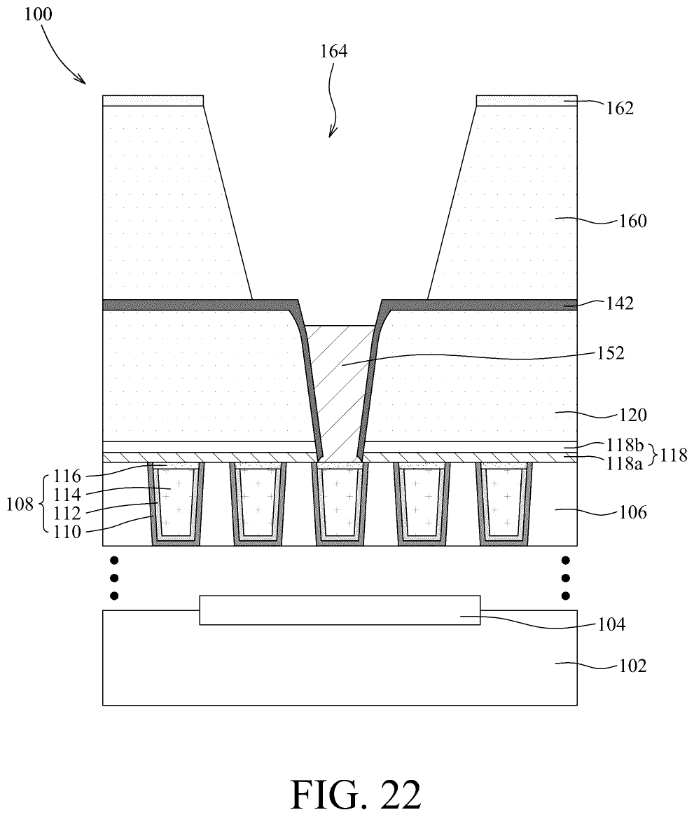

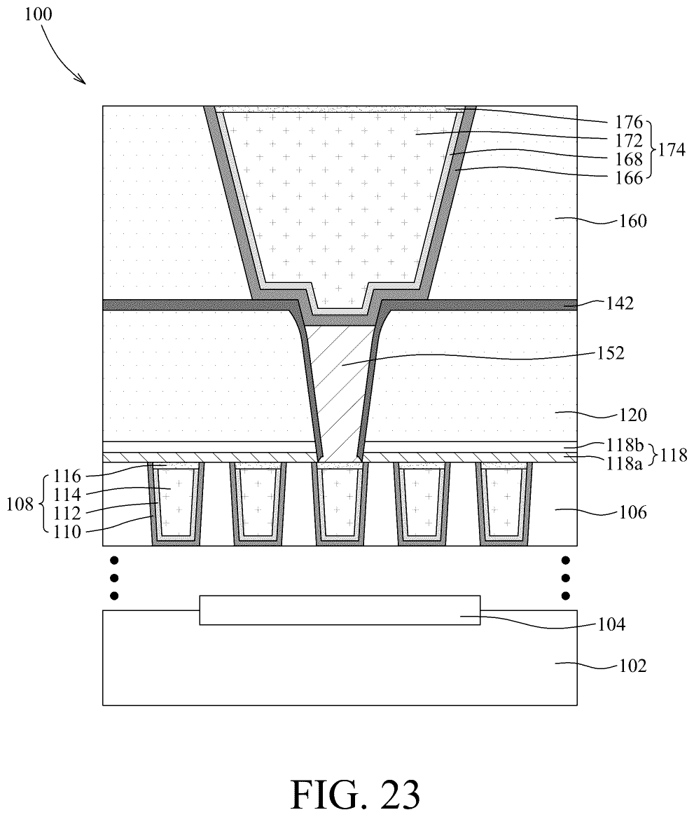

FIGS. 22-23 illustrate an alternative embodiment. Referring to FIG. 22, after the structure in FIG. 18 is derived, the trench 164 is formed by a lithography process. One difference is that the dielectric barrier layer 142 functions as an etch stop layer, such that a portion of the horizontal portion of the dielectric barrier layer 142 exposed in the trench 164 remains. In other words, the horizontal portion of the dielectric barrier layer 142 extends continuously from its vertical portion, and the top surface of the dielectric layer 120 remains covered by the dielectric barrier layer 142 and is not exposed in the trench 164. The etching process may optionally recess a top portion of the contact via 152 to below a top surface of the dielectric layer 120, as depicted in FIG. 22. Referring to FIG. 23, the metal line 174 is formed in the trench 164. As shown in FIG. 23, the barrier layer 166 lines the sidewalls and the bottom surface of the trench 164 and separates the liner 168 from contacting the contact via 152.

Similar to the alternative embodiment as depicted in FIGS. 14-16, FIG. 24 illustrates an alternative embodiment of the resultant structure in FIG. 23, in which the top surface of the contact via 152 is covered by the liner 168 instead of the barrier layer 166. No barrier layer 166 is formed on the exposed top surface of the contact via 152 due to an inhibitor film deposited on the exposed metal surface that inhibits the barrier deposition. The bottom surface of the metal fill layer 172 protrudes downwardly and may be lower than a top surface of the horizontal portion of the barrier layer 166, and/or even lower than a top surface of the horizontal portion of the dielectric barrier layer 142.

Referring back to FIG. 1, as discussed above, the conductive features 108 may represent contact plugs at the Contact level or metal lines formed in an Mx level, the contact via(s) 152 may represent contact via(s) formed in the Via_x level, and the metal line(s) 174 may represent metal line(s) formed in the Mx+1 level. The embodiments of the present disclosure have some advantageous features. By forming a barrier layer after the formation of an inhibitor film, since the growth of the inhibitor film on different materials is selective, the resulting barrier layer is selectively formed on the sidewalls of the low-k dielectric layer to perform the diffusion-blocking function, and is not formed on the underlying interface of contacting to avoid causing an increase in the via contact resistance.

In one exemplary aspect, the present disclosure is directed to a method of manufacturing a semiconductor device. The method includes forming a conductive feature in a first dielectric layer, depositing a second dielectric layer over the conductive feature, forming a first opening in the second dielectric layer to expose a top surface of the conductive feature, selectively depositing an inhibitor film on the top surface of the conductive feature, depositing a dielectric barrier layer on sidewalls of the first opening, removing the inhibitor film to expose the top surface of the conductive feature, depositing a conductive material over the dielectric barrier layer and filling the first opening, and performing a planarization process to expose the dielectric barrier layer. In some embodiments, the inhibitor film includes silane. In some embodiments, the selectively depositing of the inhibitor film includes a self-assembled-monolayer (SAM) process. In some embodiments, the conductive material is in contact with the dielectric barrier layer. In some embodiments, after the performing of the planarization process, a top surface of the second dielectric layer is exposed. In some embodiments, after the performing of the planarization process, a top surface of the second dielectric layer remains covered by a horizontal portion of the dielectric barrier layer. In some embodiments, the method further includes after the performing of the planarization process, depositing a third dielectric layer over the planarized conductive material, forming a second opening in the third dielectric layer to expose a top surface of the planarized conductive material, depositing a barrier layer on sidewalls of the second opening, and depositing a metal fill layer over the barrier layer and filing the second opening. In some embodiments, the barrier layer is formed of a conductive material. In some embodiments, the planarized conductive material is in contact with the dielectric barrier layer, and the method further includes depositing a liner over the barrier layer, the liner separates the metal fill layer from contacting the barrier layer. In some embodiments, the liner is in contact with the top surface of the planarized conductive material.

In another exemplary aspect, the present disclosure is directed to a method of forming a semiconductor structure. The method includes forming a conductive feature in a first dielectric layer, depositing a second dielectric layer over the first dielectric layer, forming a contact via through the second dielectric layer and landing on a top surface of the conductive feature, the contact via separated from the second dielectric layer by a dielectric barrier layer, forming a third dielectric layer over the second dielectric layer, and forming a metal line in the third dielectric layer and in electrical coupling with the contact via. The metal line includes a metal fill layer separated from the third dielectric layer by a conductive barrier layer. In some embodiments, the forming of the contact via includes forming a first opening in the second dielectric layer to expose the top surface of the conductive feature, selectively depositing an inhibitor film on the top surface of the conductive feature, depositing the dielectric barrier layer on sidewalls of the first opening, depositing a conductive material over the dielectric barrier layer and filling the first opening, and planarizing the conductive material as the contact via. In some embodiments, the forming of the contact via further includes after the depositing of the dielectric barrier layer, removing the inhibitor film. In some embodiments, the forming of the metal line includes forming a second opening in the third dielectric layer to expose a top surface of the contact via, depositing the conductive barrier layer on sidewalls of the second opening, depositing the metal fill layer over the conductive barrier layer and filling the second opening, and planarizing the metal fill layer. In some embodiments, the forming of the metal line further includes forming a metal capping layer over the metal fill layer. In some embodiments, the forming of the metal line further includes selectively depositing an inhibitor film on the top surface of the contact via, after the depositing of the conductive barrier layer, removing the inhibitor film to expose the top surface of the contact via, and depositing a liner over the conductive barrier layer and in contact with the top surface of the contact via.

In yet another exemplary aspect, the present disclosure is directed to an interconnect structure. The interconnect structure includes a conductive feature disposed in a first dielectric layer, a second dielectric layer over the first dielectric layer, a contact via extending through the second dielectric layer and landing on a top surface of the conductive feature, a dielectric barrier layer separating the contact via from the second dielectric layer, a third dielectric layer over the second dielectric layer, and a metal line disposed in the third dielectric layer and landing on a top surface of the contact via, the metal line including a barrier layer separating a metal fill layer from contacting the third dielectric layer. In some embodiments, the barrier layer is a conductive barrier layer. In some embodiments, the metal line further includes a liner disposed between the barrier layer and the metal fill layer, and wherein the liner is in contact with the top surface of the contact via. In some embodiments, a horizontal portion of the dielectric barrier layer covers a top surface of the second dielectric layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a conductive feature in a first dielectric layer;
depositing a second dielectric layer over the conductive feature;
forming a first opening in the second dielectric layer to expose a top surface of the conductive feature;
selectively depositing an inhibitor film on the top surface of the conductive feature;
depositing a dielectric barrier layer on sidewalls of the first opening;
removing the inhibitor film to expose the top surface of the conductive feature;
depositing a conductive material over the dielectric barrier layer and filling the first opening; and
performing a planarization process to expose the dielectric barrier layer.

2. The method of claim 1, wherein the inhibitor film includes silane.

3. The method of claim 1, wherein the selectively depositing of the inhibitor film includes a self-assembled-monolayer (SAM) process.

4. The method of claim 1, wherein the conductive material is in contact with the dielectric barrier layer.

5. The method of claim 1, wherein after the performing of the planarization process, a top surface of the second dielectric layer is exposed.

6. The method of claim 1, wherein after the performing of the planarization process, a top surface of the second dielectric layer remains covered by a horizontal portion of the dielectric barrier layer.

7. The method of claim 1, further comprising:
after the performing of the planarization process, depositing a third dielectric layer over the planarized conductive material;
forming a second opening in the third dielectric layer to expose a top surface of the planarized conductive material;
depositing a barrier layer on sidewalls of the second opening; and
depositing a metal fill layer over the barrier layer and filing the second opening.

8. The method of claim 7, wherein the barrier layer is formed of a conductive material.

9. The method of claim 7, wherein the planarized conductive material is in contact with the dielectric barrier layer, the method further comprising:
depositing a liner over the barrier layer, the liner separates the metal fill layer from contacting the barrier layer.

10. The method of claim 9, wherein the liner is in contact with the top surface of the planarized conductive material.

11. A method of forming a semiconductor structure, comprising:
forming a conductive feature in a first dielectric layer;
depositing a second dielectric layer over the first dielectric layer;
forming a contact via through the second dielectric layer and landing on a top surface of the conductive feature, wherein the contact via is separated from the second dielectric layer by a dielectric barrier layer;
forming a third dielectric layer over the second dielectric layer; and
forming a metal line in the third dielectric layer and in electrical coupling with the contact via, wherein the metal line includes a metal fill layer separated from the third dielectric layer by a conductive barrier layer.

12. The method of claim 11, wherein the forming of the contact via includes:
forming a first opening in the second dielectric layer to expose the top surface of the conductive feature;
selectively depositing an inhibitor film on the top surface of the conductive feature;
depositing the dielectric barrier layer on sidewalls of the first opening;
depositing a conductive material over the dielectric barrier layer and filling the first opening; and
planarizing the conductive material as the contact via.

13. The method of claim 12, wherein the forming of the contact via further includes:
after the depositing of the dielectric barrier layer, removing the inhibitor film.

14. The method of claim 11, wherein the forming of the metal line includes:
forming a second opening in the third dielectric layer to expose a top surface of the contact via;
depositing the conductive barrier layer on sidewalls of the second opening;
depositing the metal fill layer over the conductive barrier layer and filling the second opening; and
planarizing the metal fill layer.

15. The method of claim 14, wherein the forming of the metal line further includes:
forming a metal capping layer over the metal fill layer.

16. The method of claim 14, wherein the forming of the metal line further includes:
selectively depositing an inhibitor film on the top surface of the contact via;
after the depositing of the conductive barrier layer, removing the inhibitor film to expose the top surface of the contact via; and
depositing a liner over the conductive barrier layer and in contact with the top surface of the contact via.

17. An interconnect structure, comprising:
a conductive feature disposed in a first dielectric layer;
a second dielectric layer over the first dielectric layer;
a contact via extending through the second dielectric layer and landing on a top surface of the conductive feature;
a dielectric barrier layer separating the contact via from the second dielectric layer;
a third dielectric layer over the second dielectric layer; and
a metal line disposed in the third dielectric layer and landing on a top surface of the contact via, the metal line including a barrier layer separating a metal fill layer from contacting the third dielectric layer.

18. The interconnect structure of claim 17, wherein the barrier layer is a conductive barrier layer.

19. The interconnect structure of claim 17, wherein the metal line further includes a liner disposed between the barrier layer and the metal fill layer, and wherein the liner is in contact with the top surface of the contact via.

20. The interconnect structure of claim 17, wherein a horizontal portion of the dielectric barrier layer covers a top surface of the second dielectric layer.
